(19) United States
(12) Patent Application Publication
(10) Pub. No.: US 2010/0237358 A1
(43) Pub. Date: Sep. 23, 2010

(54) LIGHT-EMITTING DEVICE AND LIGHT-EMITTING MODULE

(75) Inventor: Tetsuo NISHIDA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/722,644

(22) Filed: Mar. 12, 2010

(30) Foreign Application Priority Data
Mar. 23, 2009 (JP) 2009-069695

(51) Int. Cl. H01L 33/00

(52) U.S. Cl. 257/84; 257/98; 257/E33.077; 257/E33.067

(57) ABSTRACT

A light-emitting device includes: a substrate sectioned into a first region and a second region; a first clad layer provided over the substrate in the first region; an active layer provided over the first clad layer and having an emission surface on at least one side surface; a second clad layer provided over the active layer; and a light dividing section arranged over the substrate in the second region and on an optical path of light emitted from the emission surface, wherein the light emitted from the emission surface is divided by the light dividing section into reflected light reflected on the light dividing section and transmitted light transmitted through the light dividing section.

### BACKGROUND

1. Technical Field

The present invention relates to a light-emitting device and a light-emitting module.

2. Related Art

In a semiconductor light-emitting device of an edge face emitting type, in general, formation of an emission surface is performed by cleaving. The cleaving can be performed by using, for example, a scribing device, a braking device or the like. However, in some cases, the cleaving provides insufficient positional accuracy of the emission surface depending on a device.

On the other hand, there is a technique for forming an emission surface by etching in order to improve the positional accuracy of the emission surface. However, in the etching, since etchable depth is limited, light emitted from the emission surface spreads in an up to down direction. Therefore, in some cases, a part of the light is reflected on a bottom section of an etched region. As a result, a sectional shape of the light is distorted and light having a satisfactory sectional shape cannot be obtained.

For example, in JP-A-63-318183, a bottom section of an etched region is formed in a taper shape to prevent emitted light from being reflected on the bottom section of the etched region.

### SUMMARY

An advantage of some aspects of the invention is to provide a light-emitting device that can obtain light having a satisfactory sectional shape.

According to an aspect of the invention, there is provided a light-emitting device including: a substrate sectioned into a first region and a second region; a first clad layer provided over the substrate in the first region; an active layer provided over the first clad layer and having an emission surface on at least one side surface; a second clad layer provided over the active layer; and a light dividing section arranged over the substrate in the second region and on an optical path of light emitted from the emission surface, wherein the light emitted from the emission surface is divided by the light dividing section into reflected light reflected on the light dividing section and transmitted light transmitted through the light dividing section.

With the light-emitting device according to the aspect of the invention, it is possible to obtain light having a satisfactory sectional shape.

In the description related to the invention, the word “over” is used in such a way that ‘another specific object (hereinafter referred to as “B”) is formed “over” a specific object (hereinafter referred to as “A”)’. In the description related to the invention, the word “over” is used on the assumption that B is directly formed on A in one case and B is formed on A via another object in the other case.

It is preferable that the light dividing section has a dielectric multilayer film and an incident surface of the light dividing section is formed of the dielectric multilayer film.

It is preferable that the light emitted from the emission surface has different two polarized wave components, the reflected light is light having one component of the polarized wave components, and the transmitted light is light having the other component of the polarized wave components.

It is preferable that at least a part of the active layer forms a gain region, the gain region includes an end face on a first side surface side of the active layer and an end face on a second side surface side opposed to the first side surface, and at least one of the end face on the first side surface side and the end face on the second side surface side is the emission surface.

It is preferable that the gain region is provided in a direction tilting with respect to a perpendicular of the first side surface.

It is preferable that the active layer further includes a third side surface that connects the first side surface and the second side surface in a tilting state in plan view and the light emitted from the emission surface travels in a direction parallel to the third side surface in a plan view.

It is preferable that an upper surface of the substrate has a step in a boundary between the first region and the second region, the upper surface of the substrate in the first region is higher than the upper surface of the substrate in the second region, and the light dividing section is set in contact with a step side surface formed by the step.

It is preferable that the light dividing section is a prism.

It is preferable that the light-emitting device includes a first electrode electrically connected to the first clad layer and a second electrode electrically connected to the second clad layer.

In the description related to the invention, the word “electrically connected” is used in such a way that ‘another specific member (hereinafter referred to as “D member”) is “electrically connected” to “a specific member (hereinafter referred to as “C member”)”’. In the description related to the invention, the word “electrically connected” is used on the assumption that the C member and the D member are electrically connected in direct contact with each other in one case and the C member and the D member are electrically connected via another member in the other case.

It is preferable that at least one of the first side surface and the second side surface has a plurality of the emission surfaces.

According to another aspect of the invention, there is provided a light-emitting module including: the light-emitting device according to the invention; and a light-receiving section that receives the transmitted light of the light-emitting device.

It is preferable that the light-receiving section is a photodiode.

### BRIEF DESCRIPTION OF THE DRAWINGS

The invention will be described with reference to the accompanying drawings, wherein like numbers reference like elements.

FIG. 1 is a plan view schematically showing a light-emitting device according to a first embodiment of the invention.

FIG. 2 is a sectional view schematically showing the light-emitting device according to the first embodiment.

FIG. 3 is a sectional view schematically showing a process for manufacturing the light-emitting device according to the first embodiment.

FIG. 4 is a sectional view schematically showing the process for manufacturing the light-emitting device according to the first embodiment.

FIG. 5 is a sectional view schematically showing the process for manufacturing the light-emitting device according to the first embodiment.

FIG. 6 is a sectional view schematically showing the process for manufacturing the light-emitting device according to the first embodiment.

FIG. 7 is a sectional view schematically showing the process for manufacturing the light-emitting device according to the first embodiment.

FIG. 8 is a plan view schematically showing a light-emitting device according to a second embodiment of the invention.

FIG. 9 is a schematic diagram showing a section of the light-emitting device according to the second embodiment.

FIG. 10 is a diagram of an active layer in the second embodiment in plan view from a first side surface side.

FIG. 11 is a sectional view schematically showing a light-emitting module according to a third embodiment of the invention.

### DESCRIPTION OF EXEMPLARY EMBODIMENTS

### 1. First Embodiment

1.1. Light-Emitting Device According to the First Embodiment

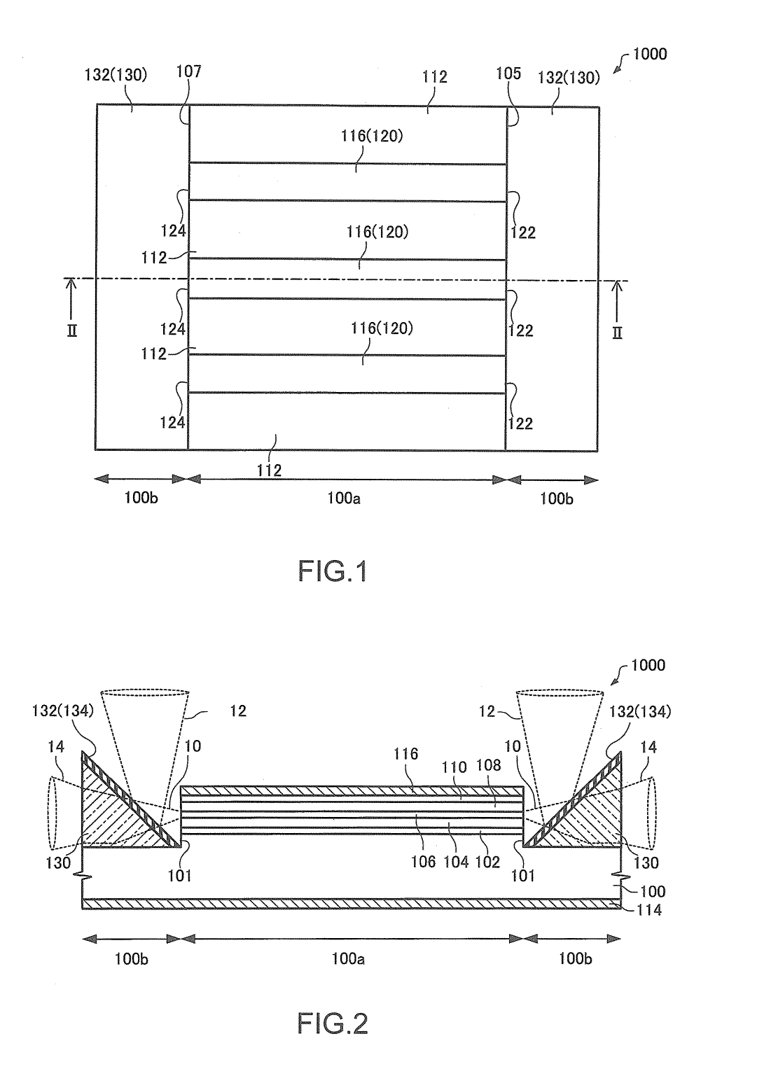

First, a light-emitting device 1000 according to a first embodiment of the invention is explained with reference to the accompanying drawings. FIG. 1 is a plan view schematically showing the light-emitting device 1000. FIG. 2 is a sectional view schematically showing the light-emitting device 1000 and is a sectional view taken along a line II-II in FIG. 1.

As shown in FIGS. 1 and 2, the light-emitting device 1000 includes a substrate 100, a first clad layer 104, an active layer 106, a second clad layer 108, and light dividing sections 130. The light-emitting device 1000 can further include a buffer layer 102, a contact layer 110, insulating layers 112, a first electrode 114, and second electrodes 116.

As the substrate 100, for example, a GaAs substrate of a first conduction type (e.g., an n type) can be used. The substrate 100 is sectioned into a first region 100a and second regions 100b. In an example shown in the figure, the substrate 100 is sectioned into the first region 100a and the second regions 100b that sandwich the first region 100a. The upper surface of the substrate 100 can have steps in boundaries between the first region 100a and the second regions 100b. In other words, the first region 100a and the second regions 100b can be sectioned by the steps. The steps are formed by etching the substrate 100 in the second regions 100b in a process for exposing side surfaces 105 and 107 of the active layer 106. Therefore, the upper surface of the substrate 100 in the first region 100a is located above the upper surface of the substrate 100 in the second regions 100b. The substrate 100 can have stepped side surfaces 101 formed by the steps. Consequently, in the light-emitting device 1000, the light dividing sections 130 explained later can be arranged to be set in contact with the stepped side surfaces 101. Therefore, the light dividing sections 130 can be accurately arranged. Although not shown in the figure, the upper surface of the substrate 100 may be a flat surface and may not have the steps. In this case, a part of the buffer layer 102 or a part of the buffer layer 102 and the first clad layer 104 may be formed on the substrate 100 in the second regions 100b.

The buffer layer 102 is formed on the substrate 100 in the first region 100a. The buffer layer 102 can improve crystallinity of a layer formed over the buffer layer 102. As the buffer layer 102, for example, a GaAs layer of the first conduction type (e.g., the n type) having more satisfactory crystallinity (e.g., lower defect density) than that of the substrate 100, and the like can be used.

The first clad layer 104 is formed on the buffer layer 102. The first clad layer 104 is formed of, for example, a semiconductor of the first conduction type. As the first clad layer 104, for example, an n-type AlGaAs layer, and the like can be used.

The active layer 106 is formed on the first clad layer 104. The active layer 106 has, for example, a multiple quantum well (MQW) structure formed by superimposing three quantum well structures including GaAs well layers and AlGaAs barrier layers. A shape of the active layer 106 is, for example, a rectangular parallelepiped (including a cube).

A part of the active layer 106 can form a plurality of gain regions as shown in FIG. 1. In the example shown in the figure, three gain regions 120 are shown. However, the number of gain regions is not specifically limited. The gain regions 120 can generate light. The light can receive gain in the gain regions 120.

The active layer 106 has a first side surface 105 and a second side surface 107 as shown in FIG. 1. The first side surface 105 and the second side surface 107 are opposed to each other. In the example shown in the figure, the first side surface 105 and the second side surface 107 are parallel to each other. The first side surface 105 and the second side surface 107 can be covered with a reflection preventing film (not shown). As the reflection preventing film, for example, a single layer of an Al₂O₃ layer and a dielectric multilayer film formed of an SiO₂ layer, an SiN layer, and an Ta₂O₅ layer, a multilayer film of these layers, and the like can be used. As shown in FIG. 1, in plan view, the gain regions 120 linearly extend from the first side surface 105 side to the second side surface 107 side. A plane shape of the gain regions 120 is, for example, a rectangle. The gain regions 120 have a first end face 122 provided on the first side surface 105 and a second end face 124 provided on the second side surface 107. The first end face 122 and the second end face 124 are surfaces opposed to each other and can form a resonator. The first end face 122 and the second end face 124 can be emission surfaces that emit light generated in the gain regions 120. One of the first end face 122 and the second end face 124 may be the emission surface. In this case, the end face on the opposite side of the emission surface may be covered with a reflecting section (not shown). The reflecting section is, for example, a dielectric multilayer film mirror and the like. In the example shown in the figure, a plurality of the first end faces 122 are provided on the first side surface 105 and a plurality of the second end faces 124 are provided on the second side surface 107. In other words, each of the side surfaces 105 and 107 of the active layer 106 has a plurality of emission surfaces.

The second clad layer 108 is formed on the active layer 106 as shown in FIG. 2. The second clad layer 108 is formed of, for example, a semiconductor of a second conduction type (e.g., a p type). As the second clad layer 108, for example, a p-type AlGaAs layer and the like can be used.

For example, the p-type second clad layer 108, the active layer 106 not doped with impurities, and the n-type first clad layer 104 form a pin diode. Each of the first clad layer 104 and the second clad layer 108 is a layer having a band gap larger than that of the active layer 106 and a refractive index smaller than that of the active layer 106. The active layer 106 can have a function of amplifying light. The first clad layer 104 and the second clad layer 108 has a function of holding the active layer 106 therebetween and trapping an injected carrier (electrons and holes) and light therein.

In the light-emitting device 1000, when forward bias voltage of the pin diode is applied between the first electrode 114 and the second electrodes 116, recombination of the electrons and holes occurs in the gain regions 120. Light emission is generated by the recombination. With the generated light as a starting point, stimulated emission occurs in a chain-like manner. The intensity of the light in the gain regions 120 is amplified. The light generated in the gain regions 120 multiply reflects between the first end faces 122 and the second end faces 124 and laser-oscillates. A part of the laser-oscillated light is emitted as emitted light 10 from the first end faces 122 and the second end faces 124.

The contact layer 110 is formed on the second clad layer 108. As the contact layer 110, a layer set in ohmic-contact with the first electrode 114 can be used. The contact layer 110 is formed of, for example, a semiconductor of the second conduction type. As the contact layer 110, for example, a p-type GaAs layer and the like can be used.

The first electrode 114 is formed over the entire surface of the bottom of the substrate 100, for example, as shown in FIG. 2. The first electrode 114 can be set in contact with the layer (in the example shown in the figure, the substrate 100) set in ohmic-contact with the first electrode 114. The first electrode 114 is electrically connected to the first clad layer 104 via the substrate 100. The first electrode 114 is one electrode for driving the light-emitting device 1000. As the first electrode 114, for example, an electrode and the like formed by stacking a Cr layer, an AuGe layer, a Ni layer, and an Au layer in this order from the substrate 100 side can be used.

The second electrode 116 is formed on the contact layer 110. The second electrode 116 is provided to correspond to each of the gain regions 120. The second electrode 116 is electrically connected to the second clad layer 108 via the contact layer 110. The second electrode 116 is another electrode for driving the light-emitting device 1000. As the second electrode 116, an electrode and the like formed by stacking a Cr layer, an AuZn layer, and an Au layer in this order from the contact layer 110 side can be used. A contact surface between the second electrode 116 and the contact layer 110 has the same plane shape as that of the gain region 120. In the example shown in the figure, a current path between the electrodes 114 and 116 is determined by the plane shape of the contact surface between the second electrode 116 and the contact layer 110. As a result, the plane shape of the gain region 120 can be determined. In other words, the light-emitting device 1000 can be a gain-guiding type. Although not shown in the figure, the light-emitting device 1000 may be a refractive index-guiding type for trapping light by surrounding the side surfaces (excluding the first end faces 122 and the second end faces 124) of the gain region 120 with members having different refractive indexes.

As shown in FIG. 1, the insulating layers 112 are formed on the contact layer 110 and in regions where the second electrodes 116 are not formed. As the insulating layers 112, for example, an SiO₂ layer, an SiN layer, and an SiON layer and the like can be used.

As shown in FIG. 2, the light dividing sections 130 are arranged on the substrate 100 in the second regions 100b and on an optical path of the emitted light 10. In the example shown in the figure, a pair of the light dividing sections 130 are provided and arranged on an optical path of the emitted light 10 emitted from the first end face 122 and an optical path of the emitted light 10 emitted from the second end face 124. The light dividing sections 130 are set in contact with, for example, the stepped side surfaces 101. The light dividing sections 130 can divide the emitted light 10 into reflected light 12 reflected on the light dividing sections 130 and transmitted light 14 transmitted through the light dividing sections 130. The light dividing sections 130 are, for example, prisms. As a material of the light dividing sections 130, for example, quartz can be used. A shape of the light dividing sections 130 is, for example, a triangle pole. In the example shown in the figure, the shape of the light dividing sections 130 is a triangle pole, a sectional shape of which is a right-angled isosceles triangle. Incident surfaces 132 of the light dividing sections 130 can be, for example, surfaces including hypotenuses of right-angled isosceles triangles. Therefore, the reflected light 12 can travel upward (in the thickness direction of the substrate 100). If an angle of the incident surfaces 132 with respect to the emitted light 10 is adjusted, the light dividing sections 130 can control a direction in which the reflected light 12 travels. A part of the emitted light 10 can change to the reflected light 12 that is reflected by the light dividing sections 130 and travels upward (in the thickness direction of the substrate 100). Therefore, in the emitted light 10, light that changes to the reflected light 12 is not reflected on the upper surface (a bottom section of an etched region) of the substrate 100 in the second regions 100b. Therefore, the light-emitting device 1000 can obtain light (the reflected light 12) having a satisfactory sectional shape. The transmitted light 14 can travel sideward (in the in-plane direction of the substrate 100).

As shown in FIG. 2, the incident surfaces 132 of the light dividing sections 130 are formed by optical layers 134. The optical layers 134 can be, for example, polarized wave selection films. Consequently, for example, when the emitted light 10 has two different polarized wave components (S polarized light and P polarized light), the light dividing sections 130 can divide one polarized wave component (e.g., the S polarized light) of the emitted light 10 as the reflected light 12 and divide the other polarized wave component (e.g., the P polarized light) as the transmitted light 14. The optical layers 134 can be, for example, reflective films. Consequently, the optical layers 134 can divide the emitted light 10 into the reflected light 12 and the transmitted light 14 having light intensity ratios corresponding to the refractive index of the optical layers 134. As the optical layers 134, for example, a dielectric multilayer film formed by a multilayer film formed by alternately stacking a TiO₂ layer and a Ta₂O₅ layer, a multilayer film formed by alternately stacking an SiO₂ layer and a TiO₂ layer, or a multilayer film formed by alternately stacking an SiO₂ layer and a Ta₂O₅ layer can be used. If the thicknesses, materials, the numbers of stacked layers, and the like of the respective layers are controlled, the optical layers 134 can obtain a required characteristic. The optical layers 134 do not have to be formed.

As an example of the light-emitting device 1000 according to this embodiment, the light-emitting device made of the GaAs material is explained above. However, any material that can form a light-emitting gain region can be used for the light-emitting device 1000. As a semiconductor material, for example, such as InGaAlP, AlGaN, InGaN, InGaAs, GaInNAs, and ZnCdSe semiconductor materials can be used.

As an example of the light-emitting device 1000 according to this embodiment, the semiconductor laser of the edge face emitting type is explained above. However, for example, a light-emitting device of the edge face emitting type such as a LED (Light Emitting Diode) of the edge face emitting type can be used as the light-emitting device 1000.

The light-emitting device 1000 has, for example, characteristics explained below.

In the light-emitting device 1000, the light dividing sections 130 can be arranged on the substrate 100 in the second regions 100b and on the optical path of the emitted light 10. A part of the emitted light 10 can be reflected by the light dividing sections 130 and change to the reflected light 12 that travels upward (in the thickness direction of the substrate 100). Therefore, in the emitted light 10, the light that changes to the reflected light 12 is not reflected on the upper surface (the bottom section of the etched region) of the substrate 100 in the second regions 100b. Therefore, the light-emitting device 1000 can obtain light (the reflected light 12) having a satisfactory sectional shape.

In the light-emitting device 1000, the first clad layer 104, the active layer 106, and the second clad layer 108 forming the light-emitting element and the light dividing sections 130 forming the optical element can be formed on the same substrate 100. In other words, in the light-emitting device 1000, the light-emitting element and the optical element can be monolithically integrated. Consequently, for example, compared with a light-emitting device in which an optical element is separately set, a reduction in size of the light-emitting device 1000 can be realized. A distance between the incident surfaces 132 of the light dividing sections 130 and the emission surfaces (the first end faces 122 and the second end faces 124) of the active layer 106 can be reduced. Therefore, it is possible to obtain light (the reflected light 12 and the transmitted light 14) having a smaller diameter in section.

In the light-emitting device 1000, the substrate 100 can have the stepped side surfaces 101 in the boundaries between the first region 100a and the second regions 100b. Consequently, in the light-emitting device 1000, the light dividing sections 130 can be arranged to be set in contact with the stepped side surfaces 101. Therefore, the light dividing sections 130 can be accurately arranged.

1.2. Method of Manufacturing the Light-Emitting Device According to the First Embodiment

A method of manufacturing the light-emitting device 100 according to the first embodiment is explained.

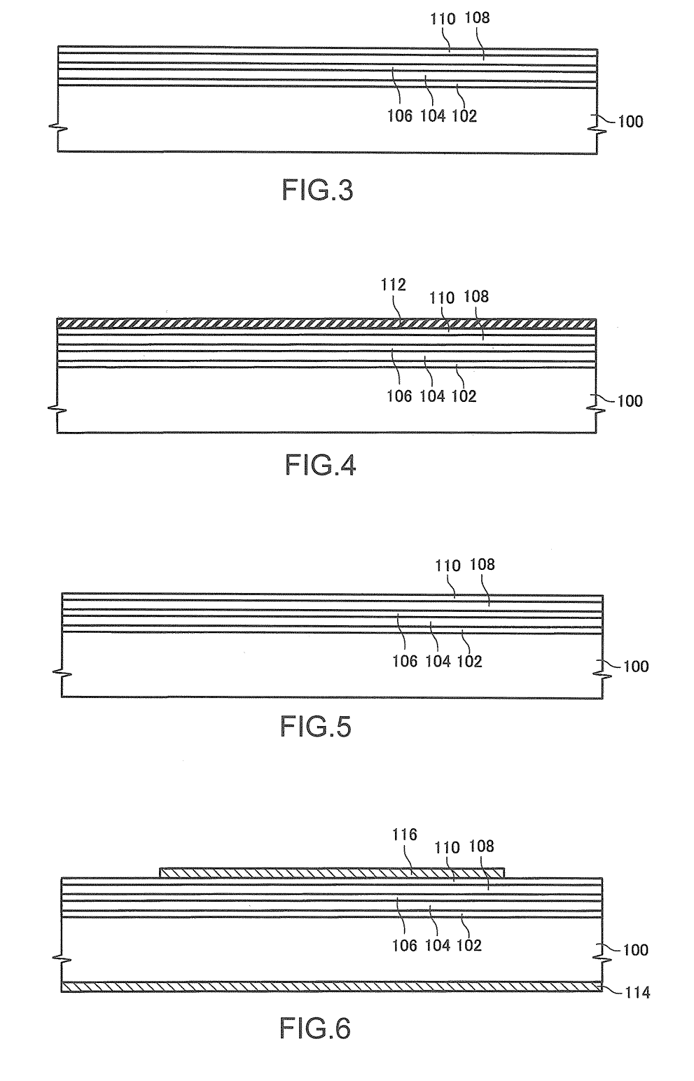

FIGS. 3 to 7 are sectional views schematically showing a process for manufacturing the light-emitting device 1000 according to the first embodiment. FIGS. 3 to 7 correspond to the sectional view shown in FIG. 2.

As shown in FIG. 3, on the substrate 100, the buffer layer 102, the first clad layer 104, the active layer 106, the second clad layer 108, and the contact layer 110 are epitaxially grown in this order. As a method of epitaxially growing the layers, for example, the MOCVD (Metal-Organic Chemical Vapor Deposition) method, the MBE (Molecular Beam Epitaxy) method, and the like can be used.

As shown in FIG. 4, the insulating layer 112 is formed on the contact layer 110. For the film formation, for example, the CVD (Chemical Vapor Deposition) method, the sputtering method, and the like can be used.

As shown in FIG. 5, the insulating layer 112 is patterned. The patterning is performed by using, for example, the photolithography technique, the etching technique and the like. Consequently, the insulating layer 112 in the region where the second electrode 116 is formed and the insulating layer 112 on the upper surface of the substrate 100 in the second regions 100b are removed.

As shown in FIG. 6, the second electrode 116 is formed. The second electrode 116 can be formed in a desired shape by, for example, a combination of the vacuum evaporation method and the lift-off method. Subsequently, the first electrode 114 is formed. The first electrode 114 is formed by the same method as the method of forming the second electrode 116 as explained above. Order of forming the first electrode 114 and the second electrode 116 is not specifically limited.

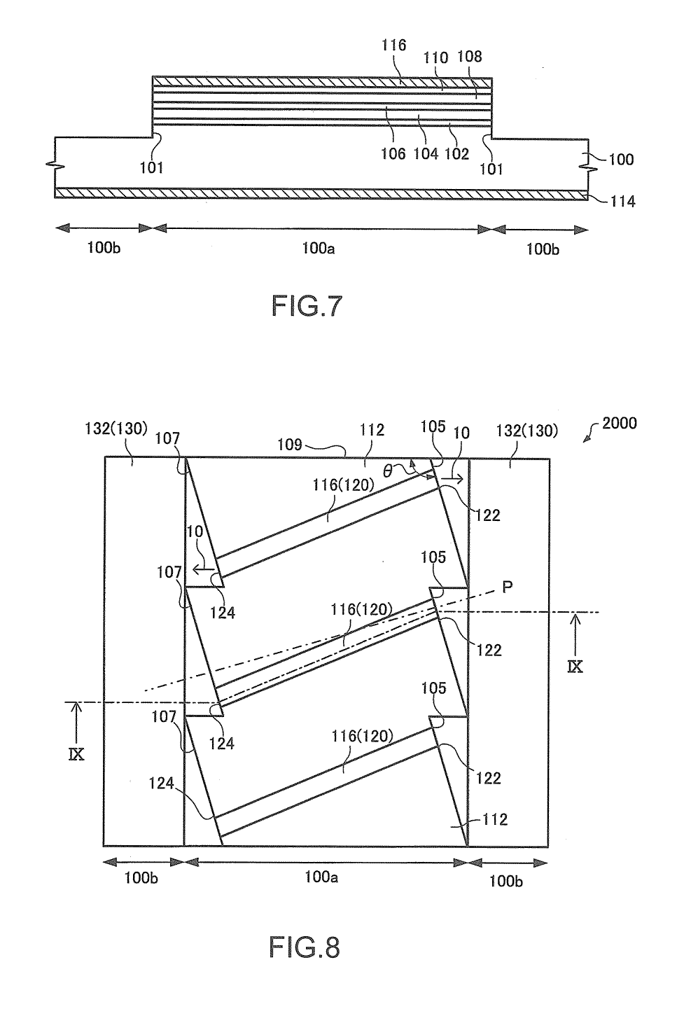

As shown in FIG. 7, a part of the substrate 100, the buffer layer 102, the first clad layer 104, the active layer 106, the second clad layer 108, and the contact layer 110 are patterned. The patterning can be performed by using, for example, dry etching. Consequently, the first side surface 105 and the second side surface 107 of the active layer 106 can be exposed. Since the side surfaces 105 and 107 of the active layer 106 can be exposed by the etching, compared with the exposure of the side surfaces 105 and 107 by cleaving, it is possible to improve positional accuracy and realize improvement of productivity. Since a part of the substrate 100 is etched in this process, a step is formed in the upper surface of the substrate 100.

A reflection preventing section (not shown) is formed in the first side surface 105 and the second side surface 107. The reflection preventing section is formed by, for example, the CVD (Chemical Vapor Deposition) method, the sputtering method, the ion assisted deposition method and the like. The method may include a process for cutting the substrate 100 for each chip with a scribing device, the braking device, or the like.

As shown in FIG. 2, the light dividing sections 130 are set on the substrate 100 in the second regions 100b and on the optical path of the emitted light 10. The light dividing sections 130 can be set on the substrate 100 in the second regions 100b by, for example, an adhesive (not shown). The substrate 100 has the stepped side surfaces 101 in the boundaries between the first region 100a and the second regions 100b. Consequently, the light dividing sections 130 can be arranged to be set in contact with the stepped side surfaces 101. Therefore, the light dividing sections 130 can be accurately arranged.

The light-emitting device 1000 can be manufactured by the process explained above.

In the method of manufacturing the light-emitting device 1000, when the light dividing sections 130 are set on the substrate 100, the light dividing sections 130 can be set in contact with the stepped side surfaces 101. Therefore, with the method of manufacturing the light-emitting device 1000, the light dividing sections 130 can be accurately arranged.

### 2. Second Embodiment

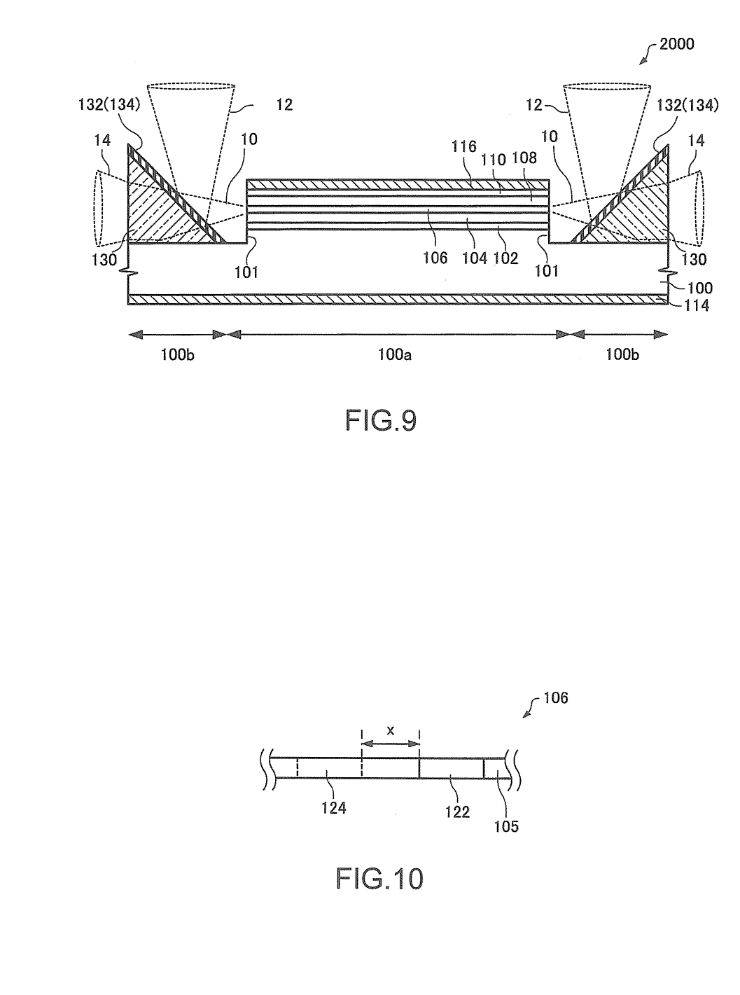

A light-emitting device 2000 according to a second embodiment of the invention is explained with reference to the accompanying drawings. FIG. 8 is a plan view schematically showing the light emitting device 2000. FIG. 9 is a diagram schematically showing a section of the light-emitting device 2000 and is a diagram showing a section taken along a line IX-IX in FIG. 8. In the following explanation, in the light-emitting device 2000 according to the second embodiment, members having the same functions as those of the light-emitting device 1000 according to the first embodiment are denoted by the same reference numerals and signs and detailed explanation of the members is omitted.

In the light-emitting device 2000, as shown in FIG. 8, the gain regions 120 are linearly provided in a direction tilting with respect to the perpendicular P of the first side surface 105 from the first side surface 105 side to the second side surface 107 side of the active layer 106. Consequently, laser oscillation of light generated in the gain regions 120 can be suppressed or prevented. FIG. 10 is a diagram of the active layer 106 in plan view from the first side surface 105 side. As shown in FIG. 10, the first end face 122 and the second end face 124 do not overlap each other. In other words, shift width x between the first end face 122 and the second end face 124 has a positive value. Consequently, the light generated in the gain regions 120 can be prevented from directly multiply reflecting between the first end face 122 and the second end face 124. As a result, since the first end face 122 and the second end face 124 are prevented from directly forming a resonator, it is possible to surely suppress or prevent laser oscillation of the light generated in the gain regions 120. Therefore, the light-emitting device 2000 can emit light that is not a laser beam. Note that the first end face 122 and the second end face 124 of one gain region 120 do not overlap each other. Although not shown in the figure, for example, the first end face 122 of one gain region 120 may overlap the second end face 124 of another gain region 120.

As shown in FIG. 8, the active layer 106 has, in plan view, a third side surface 109 that connects the first side surface 105 and the second side surface 107 in a tilting state in plan view. The third side surface 109 is connected to the first side surface 105 with a tilt of an angle θ. The tilting angle θ can be an angle at which the emitted light 10 emitted from the first end faces 122 travels in a direction parallel to the third side surface 109. The tilting angle θ can be calculated by, for example, the Snell's law. The first side surface 105 and the second side surface 107 are parallel to each other. Therefore, similarly, on the second side surface 107 side, the emitted light 10 emitted from the second end faces 124 can travel in a direction parallel to the third side surface 109 in plan view. The direction parallel to the third side surface 109 is a direction parallel to or perpendicular to the side surface of the substrate 100 in plan view. Therefore, the emitted light 10 can travel in the direction parallel to or perpendicular to the side surface of the substrate 100.

The light dividing sections 130 have the stepped side surfaces 101 in the boundaries between the first region 100a and the second regions 100b. Consequently, as shown in FIG. 8, the light dividing sections 130 can be arranged to be set in contact with a part of the stepped side surfaces 101. Therefore, the light dividing sections 130 can be accurately arranged.

The light-emitting device 2000 according to this embodiment can be applied to light sources of, for example, a projector, a display, an illuminating device, a measuring device, and the like.

The light-emitting device 2000 has, for example, characteristics explained below.

In the light-emitting device 2000, the gain regions 120 can be provided in a direction tilting with respect to the perpendicular P of the first side surface 105. In the gain regions 120, the first end faces 122 and the second end faces 124 can be set not to overlap each other in plan view from the first side surface 105 side. Consequently, as explained above, it is possible to suppress or prevent laser oscillation of light generated in the gain regions 120. Therefore, it is possible to reduce speckle noise. Further, in the light-emitting device 2000, the light generated in the gain regions 120 can travel while receiving gain in the gain regions 120 and can be emitted to the outside. Therefore, the light-emitting device 2000 can obtain power higher than that of a general LED (Light Emitting Diode) in the past. As explained above, in the light-emitting device 200, it is possible to reduce speckle noise and realize high power.

In the light-emitting device 2000, the third side surface 109 of the active layer 106 can connect the first side surface 105 and the second side surface 107 in a tilting state such that the emitted light 10 travels in the direction parallel to the third side surface 109 in plan view. Therefore, the emitted light 10 can travel in the direction parallel to or perpendicular to the side surface of the substrate 100 in plan view. In the light-emitting device 2000, even when the gain regions 120 are provided in the direction tilting with respect to the perpendicular P of the first side surface 105, the emitted light 10 parallel to or perpendicular to the side surface of the substrate 100 can be obtained.

### 3. Third Embodiment

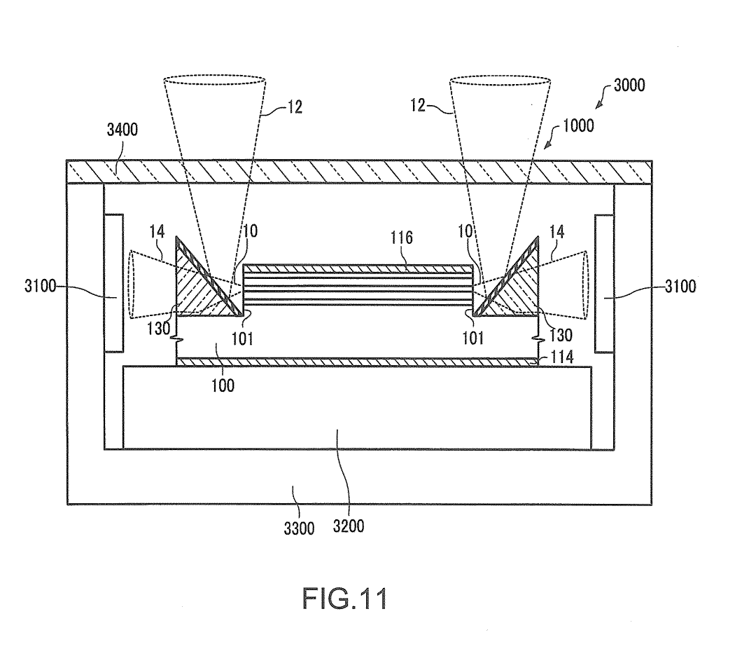

A light-emitting module 3000 having the light-emitting device 1000 according to the first embodiment is explained with reference to the accompanying drawings. FIG. 11 is a sectional view schematically showing the light-emitting module 3000. In FIG. 11, for convenience of illustration, light-receiving sections 3100 are simplified. In the light-emitting module 3000 according to a third embodiment of the invention, members having the same functions as those of the light-emitting device 1000 according to the first embodiment are denoted by the same reference numerals and signs and detailed explanation of the members is omitted.

The light-emitting module 3000 includes, as shown in FIG. 11, the light-emitting device 1000 and the light-receiving sections 3100. The light-emitting module 3000 can further include a sub-mount 3200, a package 3300, and a cover 3400.

The light-emitting device 1000 is mounted on the sub-mount 3200. The light-emitting device 1000 mounted on the sub-mount 3200 is housed in the package 3300. Although not shown in the figure, the second electrode 116 of the light-emitting device 1000 may be electrically connected to a wire on the sub-mount 3200 by, for example, wire bonding. The reflected light 12 travels upward (in the thickness direction of the substrate 100) and is transmitted through the cover 3400 and emitted to the outside. The transmitted light 14 travels sideward (in the in-plane direction of the substrate 100) and is received by the light-receiving sections 3100.

The light-receiving sections 3100 can monitor light output of the gain region 120 by receiving the transmitted light 14. In other words, in the light-emitting module 3000, the transmitted light 14 can be used as monitor light. The light-receiving sections 3100 are mounted on inner walls of the package 3300. The light-receiving sections 3100 can be provided on an optical path of the transmitted light 14. In an example shown in FIG. 11, the light-receiving sections 3100 are provided on the optical path of the transmitted light 14 and on the opposed inner walls of the package 3300, respectively. The light-receiving section 3100 may be provided on one of the opposed inner walls of the package 3300. When the active layer 106 forms a plurality of the gain regions 120, a plurality of the light-receiving sections 3100 can be provided to correspond to emission surfaces of the respective gain regions 120. Consequently, the light-receiving sections 3100 can monitor light outputs of the plurality of the gain regions 120. For example, one light-receiving section 3100 may correspond to the plurality of the gain regions 120. Consequently, for example, when a plurality of gain regions are alternately driven, a total number of light-emitting elements is reduced. It is possible to simplify an external electronic circuit (not shown) that performs voltage adjustment and the like for a light-emitting device. As the light-emitting sections 3100, for example, a photodiode can be used. As the light-emitting sections 3100, for example, a pin-type photodiode having semiconductor junction in which an intrinsic semiconductor layer is sandwiched by a p-type region and an n-type region can be used.

The sub-mount 3200 is fixed to the package 3300. As the sub-mount 3200, for example, aluminum nitride, aluminum oxide, and a copper-tungsten alloy can be used.

The package 3300 can house the light-emitting device 1000, the light-receiving sections 3100, and the sub-mount 3200. The light-receiving sections 3100 are mounted on the inner walls of the package 3300. As the package 3300, a ceramic material can be used. The package 3300 can be hermetically sealed by, for example, the cover 3400 made of a glass plate. The cover 3400 can transmit the reflected light 12.

The light-emitting module 3000 has, for example, characteristics explained below.

In the light-emitting module 3000 according to this embodiment, light outputs of the gain regions 120 can be monitored by receiving the transmitted light 14 in the light receiving sections 3100. Therefore, voltage values applied to the first electrode 114 and the second electrode 116 can be adjusted on the basis of the monitored light outputs. Consequently, the light-emitting module 3000 can reduce luminance unevenness and automatically adjust brightness. Control for feeding back light output of the light-emitting device 1000 to the applied voltage values can be performed by using, for example, an external electronic circuit (not shown).

The embodiments explained above are only examples. The invention is not limited to the embodiments. For example, it is also possible to appropriately combine the embodiments and modifications thereof.

The embodiments of the invention are explained in detail above. However, it would be obvious to those skilled in the art that a large number of modifications are possible without substantially departing from the new matters and the effects of the invention. Therefore, all such modifications are considered to be included in the scope of the invention.

The entire disclosure of Japanese Patent Application No: 2009-069695, filed Mar. 23, 2009 is expressly incorporated by reference herein.

What is claimed is:

1. A light-emitting device comprising:
a substrate sectioned into a first region and a second region;
a first clad layer provided over the substrate in the first region;
an active layer provided over the first clad layer and having an emission surface on at least one side surface;
a second clad layer provided over the active layer; and
a light dividing section arranged over the substrate in the second region and on an optical path of light emitted from the emission surface, wherein
the light emitted from the emission surface is divided by the light dividing section into reflected light reflected on the light dividing section and transmitted light transmitted through the light dividing section.

2. The light-emitting device according to claim 1, wherein
the light dividing section has a dielectric multilayer film, and
an incident surface of the light dividing section is formed of the dielectric multilayer film.

3. The light-emitting device according to claim 2, wherein
the light emitted from the emission surface has different two polarized wave components,
the reflected light is light having one component of the polarized wave components, and
the transmitted light is light having the other component of the polarized wave components.

4. The light-emitting device according to claim 1, wherein
at least a part of the active layer forms a gain region,
the gain region includes an end face on a first side surface side of the active layer and an end face on a second side surface side opposed to the first side surface, and
at least one of the end face on the first side surface side and the end face on the second side surface side is the emission surface.

5. The light-emitting device according to claim 4, wherein the gain region is provided in a direction tilting with respect to a perpendicular of the first side surface.

6. The light-emitting device according to claim 5, wherein
the active layer further includes a third side surface that connects the first side surface and the second side surface in a tilting state in plan view, and
the light emitted from the emission surface travels in a direction parallel to the third side surface in a plan view.

7. The light-emitting device according to claim 1, wherein
an upper surface of the substrate has a step in a boundary between the first region and the second region,
the upper surface of the substrate in the first region is higher than the upper surface of the substrate in the second region, and
the light dividing section is set in contact with a step side surface formed by the step.

8. The light-emitting device according to claim 1, wherein the light separating section is a prism.

9. The light-emitting device according to claim 1, further comprising:
a first electrode electrically connected to the first clad layer; and
a second electrode electrically connected to the second clad layer.

10. The light-emitting device according to claim 1, wherein at least one of the first side surface and the second side surface has a plurality of the emission surfaces.

11. A light-emitting module comprising:
the light-emitting device according to claim 1; and
a light-receiving section that receives the transmitted light of the light-emitting device.

12. The light-emitting module according to claim 11, wherein the light-receiving section is a photodiode.
